(19) United States
(12) Patent Application Publication
(10) Pub. No.: US 2025/0239995 A1
(43) Pub. Date: Jul. 24, 2025

(54) ACOUSTIC QUADRATURE FILTER CIRCUIT

(71) Applicant: Qorvo US, Inc., Greensboro, NC (US)

(72) Inventor: Nadim Khlat, Cugnaux (FR)

(21) Appl. No.: 18/976,517

(22) Filed: Dec. 11, 2024

Related U.S. Application Data
(60) Provisional application No. 63/622,617, filed on Jan. 19, 2024.
(60) Provisional application No. 63/573,063, filed on Apr. 2, 2024.

(51) Int. Cl. H03H 9/56; H04B 1/40

(52) U.S. Cl. CPC H03H 9/56; H04B 1/40

(57) ABSTRACT

An acoustic quadrature filter circuit is provided. Contrary to a conventional quadrature filter circuit that typically operates with a pair of inductor-based hybrid circuits (e.g., Fisher hybrids), the acoustic quadrature filter circuit disclosed herein is configured to operate based on a pair of acoustic hybrid circuits having higher Q-values than the inductor-based hybrid circuits. As a result, the acoustic quadrature filter circuit can provide lower insertion loss and reduced signal noise compared to the conventional quadrature filter circuit.

### RELATED APPLICATIONS

This application claims the benefit of U.S. provisional patent application Ser. No. 63/622,617, filed on Jan. 19, 2024, and U.S. provisional patent application Ser. No. 63/573,063, filed on Apr. 2, 2024, the disclosures of which are hereby incorporated herein by reference in their entireties.

### FIELD OF THE DISCLOSURE

The technology of the disclosure relates generally to a quadrature filter circuit.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as surface acoustic wave (SAW) resonators and bulk acoustic wave (BAW) resonators, are used in many high-frequency communication applications. In particular, SAW resonators are often employed in filter networks that operate at frequencies up to 1.8 GHZ, and BAW resonators are often employed in filter networks that operate at frequencies above 1.5 GHZ. Such filters need to have flat passbands, steep filter skirts and squared shoulders at the upper and lower ends of the passbands, and provide excellent rejection outside of the passbands. SAW and BAW-based filters also have relatively low insertion loss, tend to decrease in size as the frequency of operation increases, and are relatively stable over wide temperature ranges.

As such, SAW and BAW-based filters are the filters of choice for Fifth Generation (5G) and 5G new radio (5G-NR) wireless devices. While these demands keep raising the complexity of wireless devices, there is a constant need to reduce footprint and improve performance of acoustic filters.

### SUMMARY

Aspects disclosed in the detailed description include an acoustic quadrature filter circuit. Contrary to a conventional quadrature filter circuit that typically operates with a pair of inductor-based hybrid circuits (e.g., Fisher hybrids), the acoustic quadrature filter circuit disclosed herein is configured to operate based on a pair of acoustic hybrid circuits having higher Q-values than the inductor-based hybrid circuits. As a result, the acoustic quadrature filter circuit can provide lower insertion loss and reduced signal noise compared to the conventional quadrature filter circuit.

In one aspect, an acoustic quadrature filter circuit is provided. The acoustic quadrature filter circuit includes an input acoustic hybrid circuit. The input acoustic hybrid circuit is configured to split a transmit signal into an in-phase transmit signal and a quadrature transmit signal. The acoustic quadrature filter circuit also includes an acoustic in-phase filter. The acoustic in-phase filter is configured to pass the in-phase transmit signal in a transmit frequency and reject the in-phase transmit signal outside the transmit frequency. The acoustic quadrature filter circuit also includes an acoustic quadrature filter. The acoustic quadrature filter is configured to pass the quadrature transmit signal in the transmit frequency and reject the quadrature transmit signal outside the transmit frequency. The acoustic quadrature filter circuit also includes an output acoustic hybrid circuit. The output acoustic hybrid circuit is configured to regenerate the transmit signal from the in-phase transmit signal and the quadrature transmit signal.

In another aspect, a wireless device is provided. The wireless device includes at least one acoustic quadrature filter circuit. The at least one acoustic quadrature filter circuit includes an input acoustic hybrid circuit. The input acoustic hybrid circuit is configured to split a transmit signal into an in-phase transmit signal and a quadrature transmit signal. The at least one acoustic quadrature filter circuit also includes an acoustic in-phase filter. The acoustic in-phase filter is configured to pass the in-phase transmit signal in a transmit frequency and reject the in-phase transmit signal outside the transmit frequency. The at least one acoustic quadrature filter circuit also includes an acoustic quadrature filter. The acoustic quadrature filter is configured to pass the quadrature transmit signal in the transmit frequency and reject the quadrature transmit signal outside the transmit frequency. The at least one acoustic quadrature filter circuit also includes an output acoustic hybrid circuit. The output acoustic hybrid circuit is configured to regenerate the transmit signal from the in-phase transmit signal and the quadrature transmit signal.

In another aspect, a method for configuring an acoustic quadrature filter circuit is provided. The method includes configuring an input acoustic hybrid circuit to split a transmit signal into an in-phase transmit signal and a quadrature transmit signal. The method also includes configuring an acoustic in-phase filter to pass the in-phase transmit signal in a transmit frequency and reject the in-phase transmit signal outside the transmit frequency. The method also includes configuring an acoustic quadrature filter to pass the quadrature transmit signal in the transmit frequency and reject the quadrature transmit signal outside the transmit frequency. The method also includes configuring an output acoustic hybrid circuit to regenerate the transmit signal from the in-phase transmit signal and the quadrature transmit signal.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary conventional quadrature filter circuit wherein a pair of inductor-based hybrid circuits can cause undesirable insertion loss and noise;

FIG. 2 is a schematic diagram of an exemplary acoustic quadrature filter circuit configured according to embodiments of the present disclosure to provide lower insertion loss and reduced signal noise compared to the conventional quadrature filter circuit;

FIGS. 3A and 3B are schematic diagrams of exemplary input and output acoustic hybrid circuits that can be provided in the acoustic quadrature filter circuit of FIG. 2;

FIGS. 4A-4C are schematic diagrams of exemplary piezo-on-insulator (POI)-based input and output acoustic hybrid circuits that can be provided in the acoustic quadrature filter circuit of FIG. 2;

FIGS. 5A-5C are schematic diagrams of exemplary POI-based tunable input and output acoustic hybrid circuits that can be provided in the acoustic quadrature filter circuit of FIG. 2;

FIG. 6 is a schematic diagram of an exemplary communication device wherein the acoustic filter circuit of FIG. 4 can be provided; and

FIG. 7 is a flowchart of an exemplary process for configuring the acoustic quadrature filter circuit of FIG. 2.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include an acoustic quadrature filter circuit. Contrary to a conventional quadrature filter circuit that typically operates with a pair of inductor-based hybrid circuits (e.g., Fisher hybrids), the acoustic quadrature filter circuit disclosed herein is configured to operate based on a pair of acoustic hybrid circuits having higher Q-values than the inductor-based hybrid circuits. As a result, the acoustic quadrature filter circuit can provide lower insertion loss and reduced signal noise compared to the conventional quadrature filter circuit.

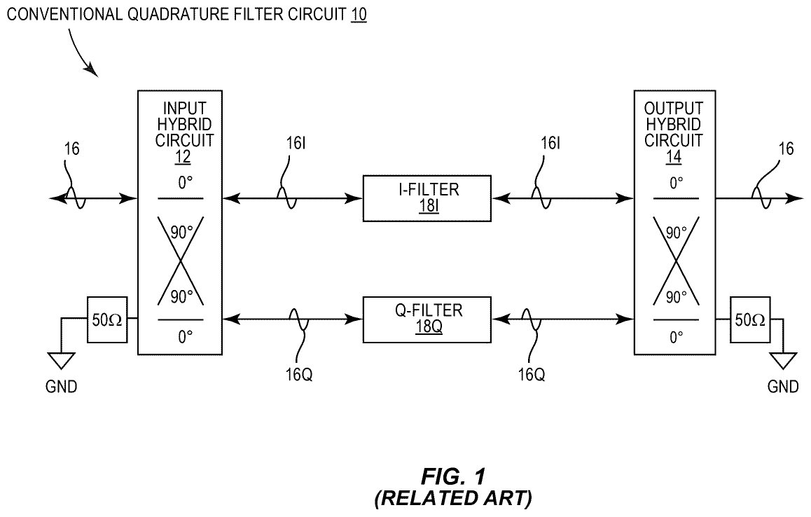

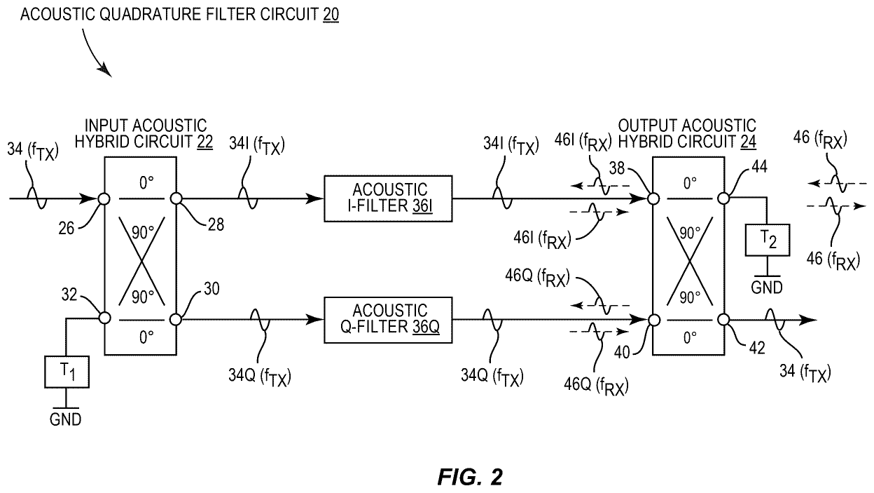

Before discussing the acoustic quadrature filter circuit of the present disclosure, starting at FIG. 2, a brief discussion of a conventional quadrature filter circuit is first provided with reference to FIG. 1 to help understand the technical problem to be solved herein.

FIG. 1 is a schematic diagram of an exemplary conventional quadrature filter circuit 10 wherein an input hybrid circuit 12 and an output hybrid circuit 14 can cause undesirable insertion loss and noise in a radio frequency (RF) signal 16. The input hybrid circuit 12 receives and splits the RF signal 16 into an in-phase signal 16I and a quadrature signal 16Q that has a ninety-degree (90°) phase shift from the in-phase signal 16I. The in-phase signal 16I passes through an in-phase filter 18I, whereas the quadrature signal 16Q passes through a quadrature filter 18Q. Each of the in-phase filter 18I and the quadrature filter 18Q is configured to pass a respective one of the in-phase signal 16I and the quadrature signal 16Q in a desired frequency, and block or reflect the respective one of the in-phase signal 16I and the quadrature signal 16Q outside the desired frequency. The output hybrid circuit 14, on the other hand, combines the in-phase signal 16I and the quadrature signal 16Q to regenerate and output the RF signal 16.

Notably, in the conventional quadrature filter circuit 10, the input hybrid circuit 12 and the output hybrid circuit 14 are inductor-based hybrid circuits (e.g., Fisher hybrids) that are typically associated with a lower Q-value. As a result, the input hybrid circuit 12 and the output hybrid circuit 14 can raise the noise level in the in-phase signal 16I and the quadrature signal 16Q. Consequently, the in-phase filter 18I and the quadrature filter 18Q must be configured sophisticatedly enough to lower the noise level, which may inadvertently create unwanted insertion loss in the conventional quadrature filter circuit 10. Hence, the technical problem to be solved herein is to reduce both the noise level and the insertion loss to thereby improve performance of the conventional quadrature filter circuit 10.

In this regard, FIG. 2 is a schematic diagram of an exemplary acoustic quadrature filter circuit 20 that can be configured according to embodiments of the present disclosure to solve the technical problem associated with the conventional quadrature filter circuit 10 of FIG. 1. Specifically, the input hybrid circuit 12 and the output hybrid circuit 14 in the conventional quadrature filter circuit 10 are replaced by an input acoustic hybrid circuit 22 and an output acoustic hybrid circuit 24, respectively. Because the input acoustic hybrid circuit 22 and the output acoustic hybrid circuit 24 each has a higher Q-value compared to the input hybrid circuit 12 and the output hybrid circuit 14, the acoustic quadrature filter circuit 20 can reduce the noise level in the conventional quadrature filter circuit 10.

In an embodiment, the input acoustic hybrid circuit 22 includes an input port 26, an in-phase port 28, a quadrature port 30, and an isolation port 32. The input acoustic hybrid circuit 22 receives a transmit signal 34 in a transmit frequency (f_{TX}) via the input port 26 and outputs an in-phase transmit signal 34I and a quadrature transmit signal 34Q via the in-phase port 28 and the quadrature port 30, respectively. Notably, each of the in-phase transmit signal 34I and the quadrature transmit signal 34Q is in the same transmit frequency (f_{TX}) as the transmit signal 34 but has one-half (½) the power of the transmit signal 34. The isolation port 32 may be terminated by a respective terminator T₁ (e.g., 500 Ω).

Each of the in-phase transmit signal 34I and the quadrature transmit signal 34Q passes through a respective one of an acoustic in-phase filter 36I and an acoustic quadrature filter 36Q. In a preferred embodiment, each of the acoustic in-phase filter 36I and the acoustic quadrature filter 36Q includes an identical type of acoustic resonator(s) as in the input acoustic hybrid circuit 22 and the output acoustic hybrid circuit 24. However, in an alternative embodiment, each of the acoustic in-phase filter 36I and the acoustic quadrature filter 36Q may also include a different type of acoustic resonator(s).

Herein, the acoustic in-phase filter 36I and the acoustic quadrature filter 36Q are configured to only pass the in-phase transmit signal 34I and the quadrature transmit signal 34Q, respectively, in the transmit frequency (f_{TX}). In this regard, the acoustic in-phase filter 36I and the acoustic quadrature filter 36Q can block (or reflect) any signal outside the transmit frequency (f_{TX}). Understandably, since the acoustic in-phase filter 36I and the acoustic quadrature filter 36Q can have a higher Q-value than the in-phase filter 18I and the quadrature filter 18Q, the acoustic quadrature filter circuit 20 can further reduce the insertion loss in the conventional quadrature filter circuit 10.

The output acoustic hybrid circuit 24 includes an in-phase port 38, a quadrature port 40, an output port 42, and an isolation port 44. The output acoustic hybrid circuit 24 receives the in-phase transmit signal 34I and the quadrature transmit signal 34Q via the in-phase port 38 and the quadrature port 40, respectively. The output acoustic hybrid circuit 24 combines the in-phase transmit signal 34I and the quadrature transmit signal 34Q to regenerate the transmit signal 34 and outputs the transmit signal 34 via the output port 42. Herein, the transmit signal 34 outputted by the output acoustic hybrid circuit 24 is in the same transmit frequency (f_{TX}) and has the same power as the transmit signal 34 received by the input acoustic hybrid circuit 22 but with a 90° phase shift. The isolation port 44 may be terminated by a respective terminator T₂ (e.g., 50 Ω).

As mentioned earlier, the acoustic in-phase filter 36I and the acoustic quadrature filter 36Q are configured to block (or reflect) any signal outside the transmit frequency (f_{TX}). As such, the acoustic in-phase filter 36I and the acoustic quadrature filter 36Q can provide adequate frequency isolation in the acoustic quadrature filter circuit 20.

In a non-limiting example, the isolation port 44 of the output acoustic hybrid circuit 24 can be used to receive a receive signal 46 in a receive frequency (f_{RX}) that differs from the transmit frequency (f_{TX}). The output acoustic hybrid circuit 24 may split the receive signal 46 into an in-phase receive signal 46I and a quadrature receive signal 46Q. The in-phase receive signal 46I and the quadrature receive signal 46Q, however, will be reflected by the acoustic in-phase filter 36I and the acoustic quadrature filter 36Q back to the output acoustic hybrid circuit 24 and recombined back to the receive signal 46. As a result, the acoustic quadrature filter circuit 20 can effectively isolate the receive frequency (f_{RX}) from the transmit frequency (f_{TX}).

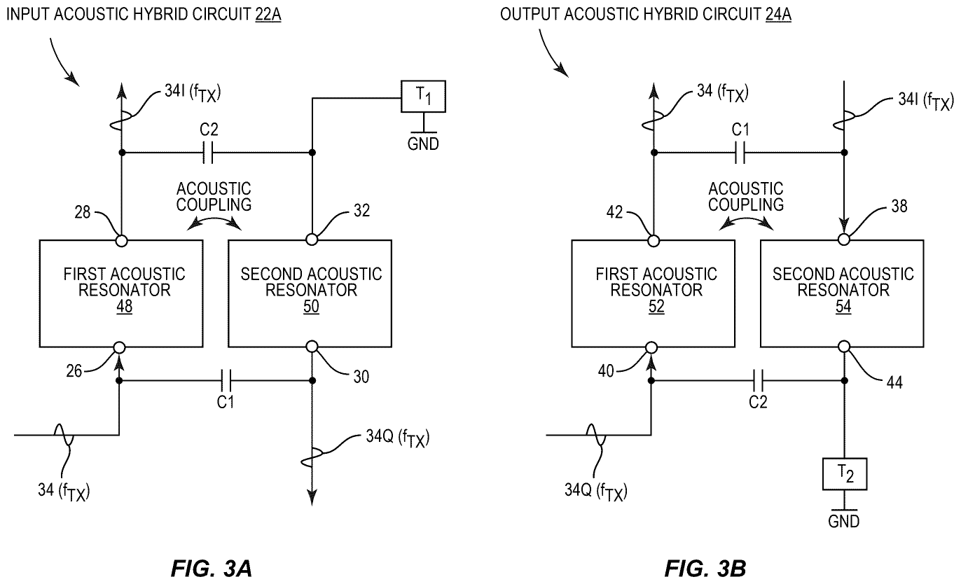

The input acoustic hybrid circuit 22 and the output acoustic hybrid circuit 24 can be configured according to various embodiments of the present disclosure. FIG. 3A is a schematic diagram of exemplary input acoustic hybrid circuit 22A that can be provided in the acoustic quadrature filter circuit 20 of FIG. 2 to function as the input acoustic hybrid circuit 22. Common elements between FIGS. 2 and 3A are shown therein with common element numbers and will not be re-described herein.

Herein, the input acoustic hybrid circuit 22A includes a respective first acoustic resonator 48 and a respective second acoustic resonator 50. The first acoustic resonator 48 is coupled between the input port 26 and the in-phase port 28. The first acoustic resonator 48 receives the transmit signal 34 via the input port 26 and outputs the in-phase transmit signal 34I via the in-phase port 28. The second acoustic resonator 50 is coupled between the quadrature port 30 and the isolation port 32. The second acoustic resonator 50 is acoustically coupled to the first acoustic resonator 48 and outputs the quadrature transmit signal 34Q via the quadrature port 30. In an embodiment, the input port 26 and the quadrature port 30 are also coupled by a first capacitor C1, whereas the in-phase port 28 and the isolation port 32 are coupled by a second capacitor C2. In a non-limiting example, the first capacitor C1 and the second capacitor C2 are configured to have an identical capacitance.

FIG. 3B is a schematic diagram of an exemplary output acoustic hybrid circuit 24A that can be provided in the acoustic quadrature filter circuit 20 of FIG. 2 to function as the output acoustic hybrid circuit 24. Common elements between FIGS. 2 and 3B are shown therein with common element numbers and will not be re-described herein.

Herein, the output acoustic hybrid circuit 24A includes a respective first acoustic resonator 52 and a respective second acoustic resonator 54. The first acoustic resonator 52 is coupled between the quadrature port 40 and the output port 42. The first acoustic resonator 52 receives the quadrature transmit signal 34Q via the quadrature port 40 and outputs the transmit signal 34 via the output port 42. The second acoustic resonator 54 is coupled between the in-phase port 38 and the isolation port 44. The second acoustic resonator 54 is acoustically coupled to the first acoustic resonator 52 and receives the in-phase transmit signal 34I via the in-phase port 38. In an embodiment, the output port 42 and the in-phase port 38 are also coupled by a first capacitor C1, whereas the quadrature port 40 and the isolation port 44 are coupled by a second capacitor C2. In a non-limiting example, the first capacitor C1 and the second capacitor C2 are configured to have an identical capacitance.

In an embodiment, the first acoustic resonator 48 and the second

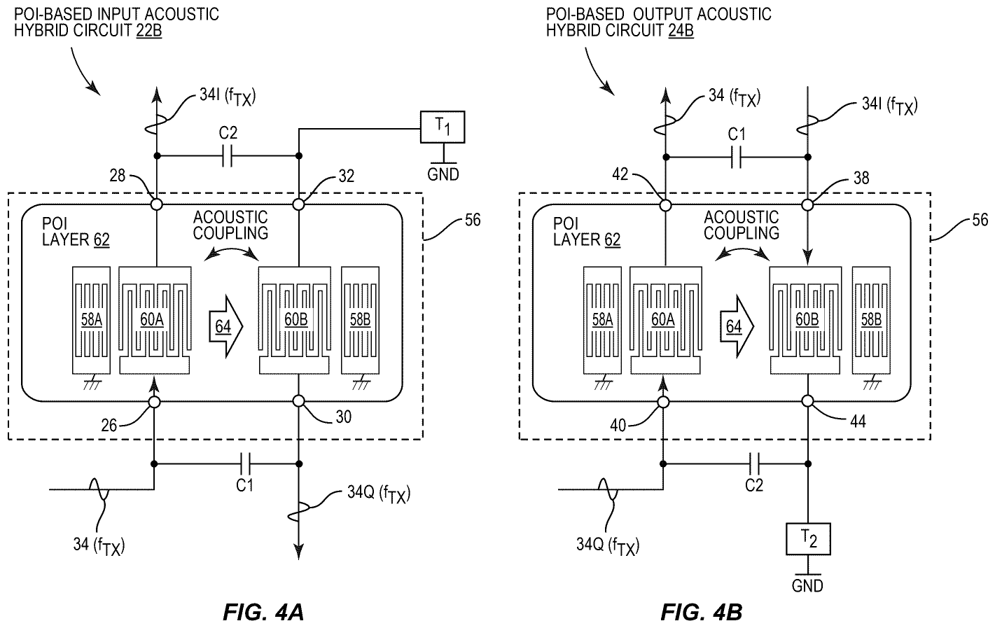

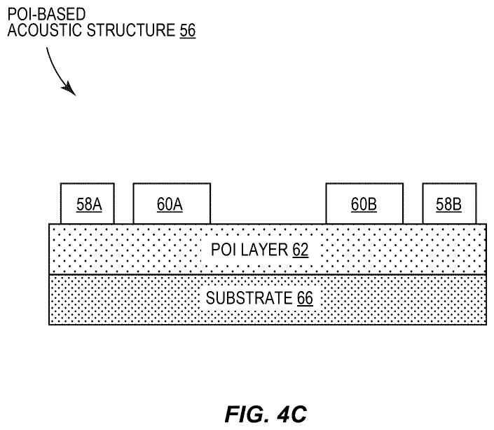

acoustic resonator 50 in the input acoustic hybrid circuit 22A, and the first acoustic resonator 52 and the second acoustic resonator 54 in the output acoustic hybrid circuit 24A can each be implemented by a piezo-on-insulator (POI)-based acoustic structure, which is discussed in detail with reference to FIGS. 4A-4C. Common elements between FIGS. 2, 3A-3B, and 4A-4C are shown therein with common element numbers and will not be re-described herein.

FIG. 4A illustrates a POI-based input acoustic hybrid circuit 22B that can function as the input acoustic hybrid circuit 22 in FIG. 2. The POI-based input acoustic hybrid circuit 22B includes a POI-based acoustic structure 56. The

POI-based acoustic structure 56 includes a pair of reflectors 58A, 58B and a pair of interdigital transducers (IDTs) 60A, 60B. The reflectors 58A, 58B and the IDTs 60A, 60B are all provided on a POI layer 62. Herein, the IDTs 60A, 60B are provided in between the reflectors 58A, 58B.

Herein, the first IDT 60A is coupled between the input port 26 and the in-phase port 28 and configured to receive the transmit signal 34 via the input port 26 and output the in-phase transmit signal 34I via the in-phase port 28. The second IDT 60B, on the other hand, is coupled between the quadrature port 30 and the isolation port 32. The second IDT 60B is acoustically coupled to the first IDT 60A by an acoustic wave 64 to thereby output the quadrature transmit signal 34Q via the quadrature port 30.

FIG. 4B illustrates a POI-based output acoustic hybrid circuit 24B that can function as the output acoustic hybrid circuit 24 in FIG. 2. Herein, the first IDT 60A is coupled between the quadrature port 40 and the output port 42 and configured to receive the quadrature transmit signal 34Q via the quadrature port 40 and output the transmit signal 34 via the output port 42. The second IDT 60B, on the other hand, is coupled between the in-phase port 38 and the isolation port 44. The second IDT 60B is acoustically coupled to the first IDT 60A by the acoustic wave 64 to thereby receive the in-phase transmit signal 34I via the in-phase port 38.

FIG. 4C is a schematic diagram providing an exemplary sideview of the POI-based acoustic structure 56 in FIGS. 4A and 4B. As shown herein, the POI layer 62 is stacked on a substrate 66. The reflectors 58A, 58B and the IDTs 60A, 60B are provided on the POI layer 62.

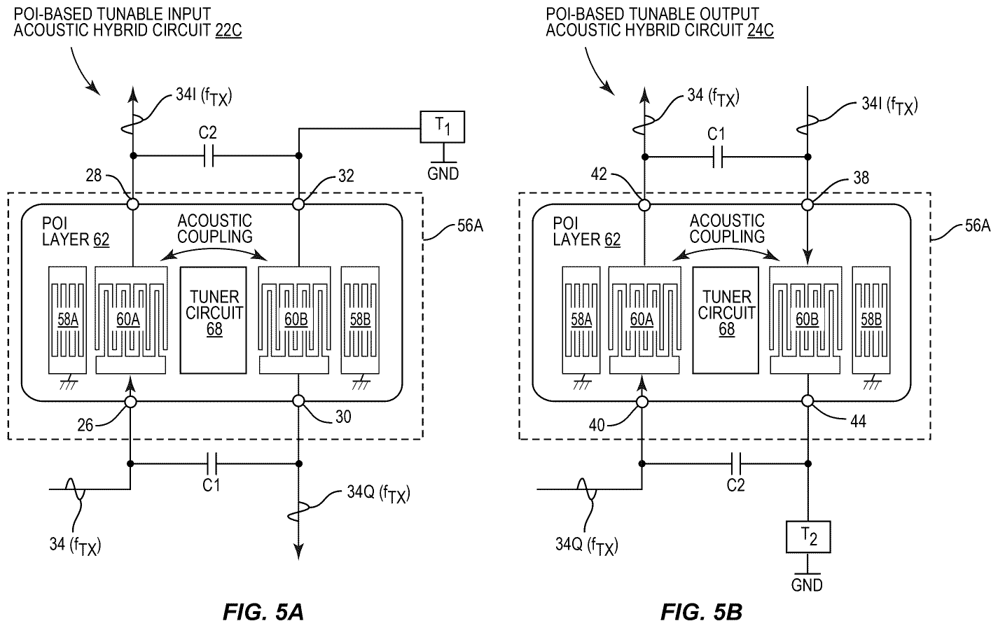

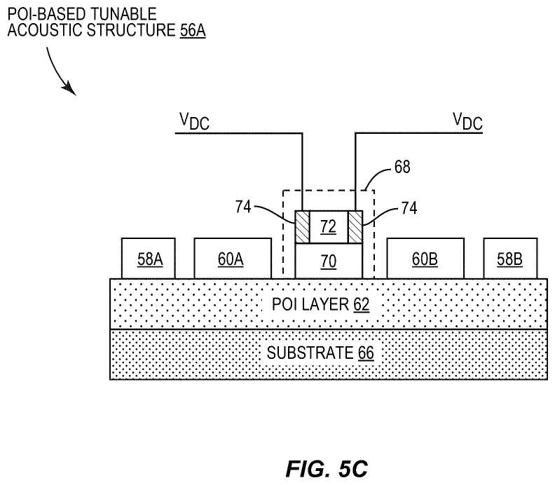

In an embodiment, the POI-based acoustic structure 56 in FIGS. 4A and 4B can be tunable to change the transmit frequency (f_{TX}), as discussed next with reference to FIGS. 5A-5C. Common elements between FIGS. 4A-4C and 5A-5C are shown therein with common element numbers and will not be re-described herein.

FIG. 5A illustrates a POI-based tunable input acoustic hybrid circuit 22C that can function as the input acoustic hybrid circuit 22 in FIG. 2. Specifically, the POI-based tunable input acoustic hybrid circuit 22C includes a POI-based tunable acoustic structure 56A that further includes a tuner circuit 68. Similarly, FIG. 5B illustrates a POI-based tunable output acoustic hybrid circuit 24C that can function as the output acoustic hybrid circuit 24 in FIG. 2. Specifically, the POI-based tunable output acoustic hybrid circuit 24C also includes the POI-based tunable acoustic structure 56A that further includes a tuner circuit 68.

FIG. 5C is a schematic diagram providing an exemplary sideview of the POI-based tunable acoustic structure 56A in FIGS. 5A and 5B. As shown herein, the tuner circuit 68 includes a silicon dioxide (SiO₂) layer 70, a silicon (Si) layer 72, and a pair of electrodes 74. The SiO₂ layer 70 is provided on the POI layer 62, and the Si layer 72 is provided on the SiO₂ layer 70. The electrodes 74 are provided on the SiO₂ layer 70 and on each side of the Si layer 72 to form a pair of lateral sides of the Si layer 72. The tuner circuit 68 can be tuned to change the transmit frequency (f_{TX}) when a direct-current (DC) voltage V_{DC} is provided to each of the electrodes 74.

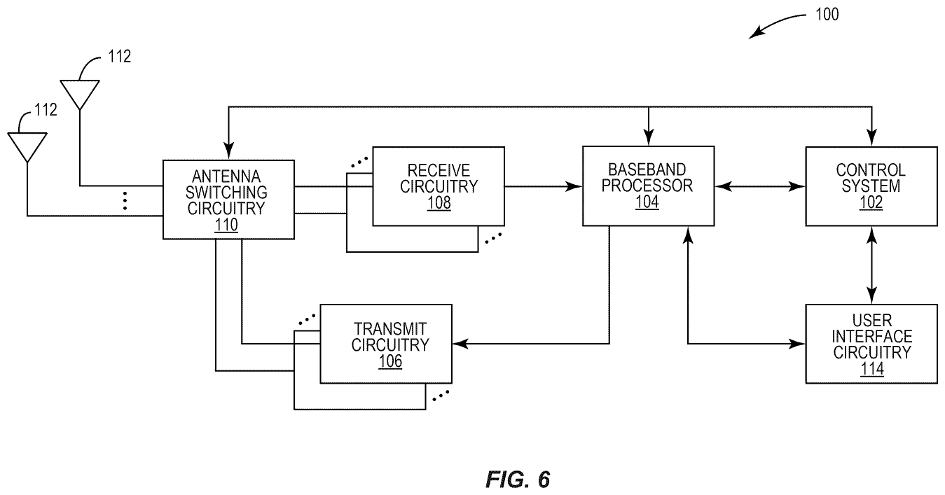

The acoustic quadrature filter circuit 20 of FIG. 2, which can include the input acoustic hybrid circuit 22A of FIG. 3A, the POI-based input acoustic hybrid circuit 22B of FIG. 4A, the POI-based tunable input acoustic hybrid circuit 22C of FIG. 5A, the output acoustic hybrid circuit 24A of FIG. 3B, the POI-based output acoustic hybrid circuit 24B of FIG. 4B, and the POI-based tunable output acoustic hybrid circuit 24C of FIG. 5B, can be provided in a communication device to support the embodiments described above. In this regard, FIG. 6 is a schematic diagram of an exemplary communication device 100 wherein the acoustic quadrature filter circuit 20 of FIG. 2 can be provided.

Herein, the communication device 100 can be any type of communication device, such as mobile terminal, smart watch, tablet, computer, navigation device, access point, base station (e.g., eNB, gNB, etc.), and like wireless communication devices that support wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In a non-limiting example, the acoustic quadrature filter circuit 20 can be provided in the transmit circuitry 106, the receive circuitry 108, and/or the antenna switching circuitry 110.

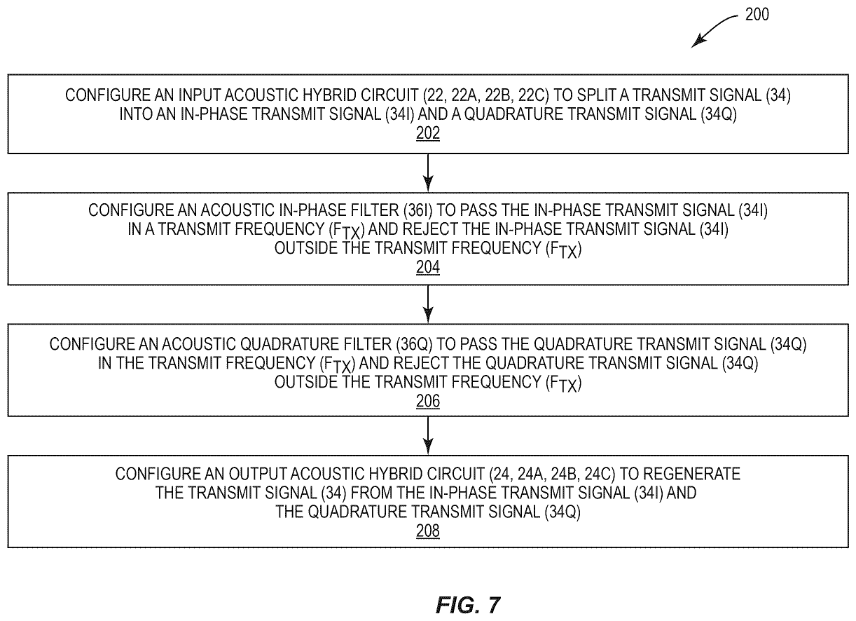

In an embodiment, it is possible to configure the acoustic quadrature filter circuit 20 of FIG. 2 in accordance with a process. In this regard, FIG. 7 is a flowchart of an exemplary process 200 for configuring the acoustic quadrature filter circuit 20 of FIG. 2.

Herein, the process 200 includes configuring one of the input acoustic hybrid circuit 22, the input acoustic hybrid circuit 22A, the POI-based input acoustic hybrid circuit 22B, and the POI-based tunable input acoustic hybrid circuit 22C to split the transmit signal 34 into the in-phase transmit signal 34I and the quadrature transmit signal 34Q (step 202). Herein, the input acoustic hybrid circuit 22, the input acoustic hybrid circuit 22A, the POI-based input acoustic hybrid circuit 22B, and the POI-based tunable input acoustic hybrid circuit 22C are referred to generally as “input acoustic hybrid circuit.” The process 200 also includes configuring the acoustic in-phase filter 36I to pass the in-phase transmit signal 34I in the transmit frequency (f_{TX}) and reject the in-phase transmit signal 34I outside the transmit frequency (f_{TX}) (step 204). The process 200 also includes configuring the acoustic quadrature filter 36Q to pass the quadrature transmit signal 34Q in the transmit frequency (f_{TX}) and reject the quadrature transmit signal 34Q outside the transmit frequency (f_{TX}) (step 206). The process 200 also includes configuring one of the output acoustic hybrid circuit 24, the output acoustic hybrid circuit 24A, the POI-based output acoustic hybrid circuit 24B, and the POI-based tunable output acoustic hybrid circuit 24C to regenerate the transmit signal 34 from the in-phase transmit signal 34I and the quadrature transmit signal 34Q (step 208). Herein, the output acoustic hybrid circuit 24, the output acoustic hybrid circuit 24A, the POI-based output acoustic hybrid circuit 24B, and the POI-based tunable output acoustic hybrid circuit 24C are referred to generally as “output acoustic hybrid circuit.”

Those skilled in the art will recognize improvements and modifications to the embodiments of the present disclosure. All such improvements and modifications are considered within the scope of the concepts disclosed herein and the claims that follow.

What is claimed is:

1. An acoustic quadrature filter circuit comprising:
an input acoustic hybrid circuit configured to split a transmit signal into an in-phase transmit signal and a quadrature transmit signal;
an acoustic in-phase filter configured to pass the in-phase transmit signal in a transmit frequency and reject the in-phase transmit signal outside the transmit frequency;
an acoustic quadrature filter configured to pass the quadrature transmit signal in the transmit frequency and reject the quadrature transmit signal outside the transmit frequency; and
an output acoustic hybrid circuit configured to regenerate the transmit signal from the in-phase transmit signal and the quadrature transmit signal.

2. The acoustic quadrature filter circuit of claim 1, wherein:
the input acoustic hybrid circuit comprises:
a respective first acoustic resonator configured to receive the transmit signal and output the in-phase transmit signal to the acoustic in-phase filter; and
a respective second acoustic resonator acoustically coupled to the first acoustic resonator and configured to output the quadrature transmit signal to the acoustic quadrature filter; and
the output acoustic hybrid circuit comprises:
a respective first acoustic resonator configured to receive the quadrature transmit signal from the acoustic quadrature filter and output the transmit signal; and
a respective second acoustic resonator acoustically coupled to the first acoustic resonator and configured to receive the in-phase transmit signal from the acoustic in-phase filter.

3. The acoustic quadrature filter circuit of claim 1, wherein each of the input acoustic hybrid circuit and the output acoustic hybrid circuit comprises an acoustic structure, the acoustic structure comprising:
a piezo-on-insulator (POI) layer provided on a substrate;
a pair of reflectors provided on the POI layer; and
a first interdigital transducer (IDT) and a second IDT provided on the POI layer in between the pair of reflectors.

4. The acoustic quadrature filter circuit of claim 3, wherein the input acoustic hybrid circuit further comprises:
an input port and a quadrature port each coupled to a first capacitor;
an in-phase port and an isolation port each coupled to a second capacitor having an identical capacitance as the first capacitor;
the first IDT coupled between the input port and the in-phase port, the first IDT is configured to receive the transmit signal via the input port and output the in-phase transmit signal via the in-phase port; and
the second IDT coupled between the quadrature port and the isolation port, the second IDT is configured to output the quadrature transmit signal via the quadrature port.

5. The acoustic quadrature filter circuit of claim 3, wherein the output acoustic hybrid circuit further comprises:
an output port and an in-phase port each coupled to a first capacitor;
a quadrature port and an isolation port each coupled to a second capacitor having an identical capacitance as the first capacitor;
the first IDT coupled between the quadrature port and the output port, the first IDT is configured to receive the quadrature transmit signal via the quadrature port and output the transmit signal via the output port; and
the second IDT coupled between the in-phase port and the isolation port, the second IDT is configured to receive the in-phase transmit signal via the in-phase port.

6. The acoustic quadrature filter circuit of claim 1, wherein each of the input acoustic hybrid circuit and the output acoustic hybrid circuit comprises an acoustic structure, the acoustic structure comprising:
a piezo-on-insulator (POI) layer provided on a substrate;
a pair of reflectors provided on the POI layer;
a first interdigital transducer (IDT) and a second IDT provided on the POI layer in between the pair of reflectors; and
a tuner circuit provided on the POI layer and in between the first IDT and the second IDT, the tuner circuit is tuned by a direct-current (DC) voltage to change the transmit frequency.

7. The acoustic quadrature filter circuit of claim 6, wherein the tuner circuit comprises:
a silicon dioxide (SiO₂) layer provided on the POI layer;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the DC voltage.

8. The acoustic quadrature filter circuit of claim 6, wherein the input acoustic hybrid circuit further comprises:
an input port and a quadrature port each coupled to a first capacitor;
an in-phase port and an isolation port each coupled to a second capacitor having an identical capacitance as the first capacitor;
the first IDT coupled between the input port and the in-phase port, the first IDT is configured to receive the transmit signal via the input port and output the in-phase transmit signal via the in-phase port; and
the second IDT coupled between the quadrature port and the isolation port, the second IDT is configured to output the quadrature transmit signal via the quadrature port.

9. The acoustic quadrature filter circuit of claim 6, wherein the output acoustic hybrid circuit further comprises:
an output port and an in-phase port each coupled to a first capacitor;
a quadrature port and an isolation port each coupled to a second capacitor having an identical capacitance as the first capacitor;
the first IDT coupled between the quadrature port and the output port, the first IDT is configured to receive the quadrature transmit signal via the quadrature port and output the transmit signal via the output port; and
the second IDT coupled between the in-phase port and the isolation port, the second IDT is configured to receive the in-phase transmit signal via the in-phase port.

10. A wireless device comprising at least one acoustic quadrature filter circuit comprising:
an input acoustic hybrid circuit configured to split a transmit signal into an in-phase transmit signal and a quadrature transmit signal;
an acoustic in-phase filter configured to pass the in-phase transmit signal in a transmit frequency and reject the in-phase transmit signal outside the transmit frequency;
an acoustic quadrature filter configured to pass the quadrature transmit signal in the transmit frequency and reject the quadrature transmit signal outside the transmit frequency; and
an output acoustic hybrid circuit configured to regenerate the transmit signal from the in-phase transmit signal and the quadrature transmit signal.

11. The wireless device of claim 10, further comprising transmit circuitry, receive circuitry, and antenna switching circuitry, wherein the at least one acoustic quadrature filter circuit can be provided in any one or more of the transmit circuitry, the receive circuitry, and the antenna switching circuitry.

12. The wireless device of claim 10, wherein:
the input acoustic hybrid circuit comprises:
a respective first acoustic resonator configured to receive the transmit signal and output the in-phase transmit signal to the acoustic in-phase filter; and
a respective second acoustic resonator acoustically coupled to the first acoustic resonator and configured to output the quadrature transmit signal to the acoustic quadrature filter; and
the output acoustic hybrid circuit comprises:
a respective first acoustic resonator configured to receive the quadrature transmit signal from the acoustic quadrature filter and output the transmit signal; and
a respective second acoustic resonator acoustically coupled to the first acoustic resonator and configured to receive the in-phase transmit signal from the acoustic in-phase filter.

13. The wireless device of claim 10, wherein each of the input acoustic hybrid circuit and the output acoustic hybrid circuit comprises an acoustic structure, the acoustic structure comprises:
a piezo-on-insulator (POI) layer provided on a substrate;
a pair of reflectors provided on the POI layer; and
a first interdigital transducer (IDT) and a second IDT provided on the POI layer in between the pair of reflectors.

14. The wireless device of claim 13, wherein the input acoustic hybrid circuit further comprises:
an input port and a quadrature port each coupled to a first capacitor;
an in-phase port and an isolation port each coupled to a second capacitor having an identical capacitance as the first capacitor;
the first IDT coupled between the input port and the in-phase port, the first IDT is configured to receive the transmit signal via the input port and output the in-phase transmit signal via the in-phase port; and
the second IDT coupled between the quadrature port and the isolation port, the second IDT is configured to output the quadrature transmit signal via the quadrature port.

15. The wireless device of claim 13, wherein the output acoustic hybrid circuit further comprises:
an output port and an in-phase port each coupled to a first capacitor;
a quadrature port and an isolation port each coupled to a second capacitor having an identical capacitance as the first capacitor;
the first IDT coupled between the quadrature port and the output port, the first IDT is configured to receive the quadrature transmit signal via the quadrature port and output the transmit signal via the output port; and
the second IDT coupled between the in-phase port and the isolation port, the second IDT is configured to receive the in-phase transmit signal via the in-phase port.

16. The wireless device of claim 10, wherein each of the input acoustic hybrid circuit and the output acoustic hybrid circuit comprises an acoustic structure, the acoustic structure comprises:
a piezo-on-insulator (POI) layer provided on a substrate;
a pair of reflectors provided on the POI layer;
a first interdigital transducer (IDT) and a second IDT provided on the POI layer in between the pair of reflectors; and
a tuner circuit provided on the POI layer and in between the first IDT and the second IDT, the tuner circuit is tuned by a direct-current (DC) voltage to change the transmit frequency.

17. The wireless device of claim 16, wherein the tuner circuit comprises:
a silicon dioxide (SiO₂) layer provided on the POI layer;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the DC voltage.

18. The wireless device of claim 17, wherein the input acoustic hybrid circuit further comprises:
an input port and a quadrature port each coupled to a first capacitor;
an in-phase port and an isolation port each coupled to a second capacitor having an identical capacitance as the first capacitor;
the first IDT coupled between the input port and the in-phase port, the first IDT is configured to receive the transmit signal via the input port and output the in-phase transmit signal via the in-phase port; and
the second IDT coupled between the quadrature port and the isolation port, the second IDT is configured to output the quadrature transmit signal via the quadrature port.

19. The wireless device of claim 16, wherein the output acoustic hybrid circuit further comprises:
an output port and an in-phase port each coupled to a first capacitor;
a quadrature port and an isolation port each coupled to a second capacitor having an identical capacitance as the first capacitor;
the first IDT coupled between the quadrature port and the output port, the first IDT is configured to receive the quadrature transmit signal via the quadrature port and output the transmit signal via the output port; and
the second IDT coupled between the in-phase port and the isolation port, the second IDT is configured to receive the in-phase transmit signal via the in-phase port.

20. A method for configuring an acoustic quadrature filter circuit comprising:
configuring an input acoustic hybrid circuit to split a transmit signal into an in-phase transmit signal and a quadrature transmit signal;
configuring an acoustic in-phase filter to pass the in-phase transmit signal in a transmit frequency and reject the in-phase transmit signal outside the transmit frequency;
configuring an acoustic quadrature filter to pass the quadrature transmit signal in the transmit frequency and reject the quadrature transmit signal outside the transmit frequency; and
configuring an output acoustic hybrid circuit to regenerate the transmit signal from the in-phase transmit signal and the quadrature transmit signal.
